(19) United States
(12) Patent Application Publication
(10) Pub. No.: US 2026/0086455 A1
(43) Pub. Date: Mar. 26, 2026

(54) METHOD FOR MANUFACTURING LAMINATE

(71) Applicant: NICHIA CORPORATION, Anan-shi (JP)

(72) Inventors: Yuki KANAGAWA, Komatsushima-shi (JP); Akihiko MITANI, Tokushima-shi (JP)

(73) Assignee: NICHIA CORPORATION, Anan-shi (JP)

(21) Appl. No.: 19/332,437

(22) Filed: Sep. 18, 2025

(30) Foreign Application Priority Data
Sep. 26, 2024 (JP) 2024-167417

(51) Int. Cl. G03F 7/00

(52) U.S. Cl. CPC G03F 7/0005

(57) ABSTRACT

A method for manufacturing a laminate includes: disposing a resist material layer on an intermediate body; exposing the resist material layer to light using a mask including a first portion, a second portion having a light transmittance lower than that of the first portion, and a third portion having a light transmittance lower than that of the second portion; developing the exposed resist material layer to form a resist layer including a first region disposed in a region corresponding to the first portion, a second region disposed in a region corresponding to the second portion, spaced apart from the intermediate body, and connected to the first region, and an opening formed in a region corresponding to the third portion; forming a covering layer on the resist layer and the intermediate body; and removing the resist layer to remove a portion of the covering layer in contact with the resist layer.

### CROSS-REFERENCE TO RELATED APPLICATIONS

This application is based upon and claims the benefit of priority from the prior Japanese Patent Application No. 2024-167417, filed on Sep. 26, 2024, the entire contents of which are incorporated herein by reference.

### BACKGROUND

The present disclosure relates to a method for manufacturing a laminate.

When a microstructure such as a light-emitting diode (LED) is manufactured, a laminate may be formed by a lift-off method. That is, a resist layer is formed on an intermediate body by a lithography method, a covering layer is formed on the intermediate body and the resist layer, and a part of the covering layer is removed together with the resist layer to pattern the covering layer into a predetermined shape. At this time, burrs may be generated on the covering layer after being patterned.

### SUMMARY

An object of an embodiment of the present disclosure is to provide a method for manufacturing a laminate, the method being capable of reducing the generation of burrs.

An embodiment of the present disclosure provides a method for manufacturing a laminate, the method including: disposing a resist material layer made of a negative photoresist on an intermediate body; exposing the resist material layer to light using a mask including a first portion, a second portion having a light transmittance lower than a light transmittance of the first portion, and a third portion having a light transmittance lower than the light transmittance of the second portion, the second portion being disposed between the first portion and the third portion in a top view; developing the exposed resist material layer to form a resist layer including a first region disposed in a region corresponding to the first portion and in contact with the intermediate body and a second region disposed in a region corresponding to the second portion, spaced apart from the intermediate body, and connected to the first region, the resist layer having an opening formed in a region corresponding to the third portion; forming a covering layer on the resist layer and on the intermediate body such that at least a part of a surface of the resist layer other than an upper surface of the resist layer is exposed; and removing the resist layer to remove a portion of the covering layer in contact with the resist layer.

An embodiment of the present disclosure can provide a method for manufacturing a laminate, the method being capable of reducing the generation of burrs.

### BRIEF DESCRIPTION OF THE DRAWINGS

FIG. 1A is a plan view illustrating a mask used in a first embodiment.

FIG. 1B is a partially enlarged plan view illustrating a region IB of FIG. 1A.

FIG. 2A is a partially enlarged plan view illustrating a region IIA of FIG. 1B.

FIG. 2B is a cross-sectional view taken along a line IIB-IIB indicated in FIG. 2A.

FIG. 3 is a cross-sectional view illustrating a method for manufacturing a laminate according to the first embodiment.

FIG. 4 is a cross-sectional view illustrating the method for manufacturing a laminate according to the first embodiment.

FIG. 5 is a cross-sectional view illustrating the method for manufacturing a laminate according to the first embodiment.

FIG. 6A is a cross-sectional view illustrating the method for manufacturing a laminate according to the first embodiment.

FIG. 6B is a cross-sectional view illustrating the method for manufacturing a laminate according to the first embodiment.

FIG. 6C is a cross-sectional view illustrating the method for manufacturing a laminate according to the first embodiment.

FIG. 7 is a cross-sectional view illustrating the method for manufacturing a laminate according to the first embodiment.

FIG. 8A illustrates a mask used in a comparative example.

FIG. 8B is a cross-sectional view illustrating a method for manufacturing a laminate according to the comparative example.

FIG. 8C is a cross-sectional view illustrating the method for manufacturing a laminate according to the comparative example.

FIG. 9 is a plan view illustrating a mask used in a modified example of the first embodiment.

FIG. 10 is a plan view illustrating a mask used in a second embodiment.

FIG. 11 is a cross-sectional view illustrating a method for manufacturing a laminate according to the second embodiment.

FIG. 12 is a cross-sectional view illustrating the method for manufacturing a laminate according to the second embodiment.

FIG. 13 is a cross-sectional view illustrating the method for manufacturing a laminate according to the second embodiment.

FIG. 14 is a plan view illustrating a mask used in a third embodiment.

FIG. 15 is a cross-sectional view illustrating a method for manufacturing a laminate according to the third embodiment.

FIG. 16 is a cross-sectional view illustrating the method for manufacturing a laminate according to the third embodiment.

### DETAILED DESCRIPTION

### First Embodiment

In the present embodiment, a laminate is manufactured by forming a covering layer on an intermediate body. The laminate is, for example, a part of a light-emitting diode. In this case, the intermediate body is, for example, a sapphire substrate, a semiconductor structure, or the like, and the covering layer is wiring or the like.

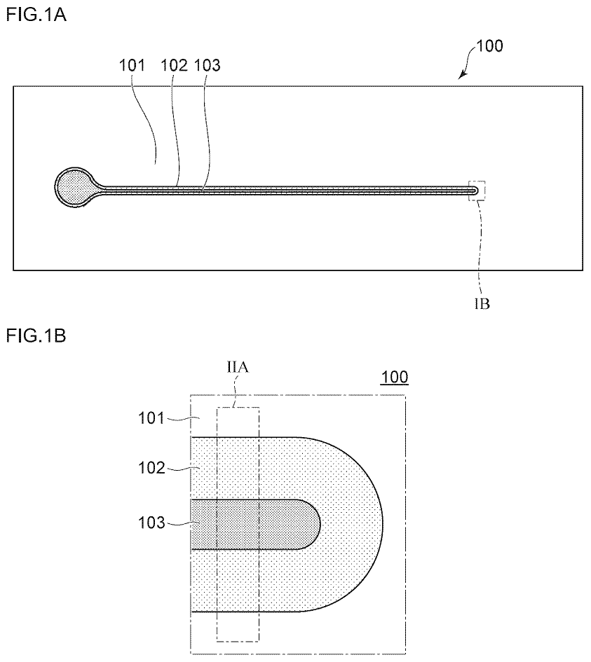

FIG. 1A is a plan view illustrating a mask used in the present embodiment.

FIG. 1B is a partially enlarged plan view illustrating a region IB of FIG. 1A.

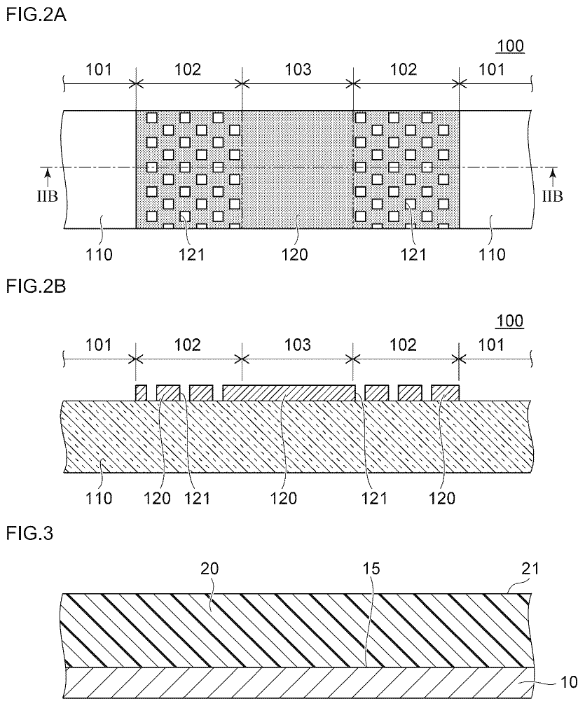

FIG. 2A is a partially enlarged plan view illustrating a region IIA of FIG. 1B.

FIG. 2B is a cross-sectional view taken along a line IIB-IIB indicated in FIG. 2A.

FIGS. 3 to 7 are each a cross-sectional view illustrating a method for manufacturing a laminate according to the present embodiment.

All the drawings are illustrated schematically and may be exaggerated or simplified as appropriate. Even when the same components are illustrated in a plurality of drawings, the shapes and numbers of the components are not necessarily exactly the same. The same applies to other schematic drawings described below. As a cross-sectional view, an end view illustrating only a cut surface may be illustrated.

### Mask 100

First, a mask used in the present embodiment will be described.

As illustrated in FIGS. 1A to 2B, a mask 100 used in the present embodiment for exposure includes a first portion 101, a second portion 102, and a third portion 103. In a top view, the second portion 102 is disposed between the third portion 103 and the first portion 101, and surrounds the third portion 103.

The mask 100 includes a light-transmissive member 110 and a metal member 120 disposed on the light-transmissive member 110. The light-transmissive member 110 is made of a material having a high light transmittance. The light-transmissive member 110 is, for example, a quartz plate. The metal member 120 is made of a material having a light transmittance lower than the light transmittance of the light-transmissive member 110. The metal member 120 is, for example, a metal layer made of chromium (Cr). In the present specification, the term “light transmittance” refers to a light transmittance with respect to a peak wavelength of light from a light source used in exposure of a resist material layer to light described below.

In the first portion 101 of the mask 100, the metal member 120 is not disposed. In the second portion 102, a plurality of openings 121 are formed in the metal member 120. The openings 121 are arranged in, for example, a rectangular lattice pattern or a triangular lattice pattern. In the example illustrated in FIG. 2A, the openings 121 formed in the metal member 120 are arranged in a square lattice pattern. The openings 121 may have, for example, a rectangular, circular, or elliptical shape in a top view. The openings 121 may have, for example, a maximum diameter in a range from 0.2 μm to 2.0 μm in a top view. In the third portion 103, the metal member 120 is disposed over the entire third portion 103.

Therefore, the area of the metal member 120 per unit area of the second portion 102 is larger than the area of the metal member 120 per unit area of the first portion 101, and the area of the metal member 120 per unit area of the third portion 103 is larger than the area of the metal member 120 per unit area of the second portion 102. In the above-described example, the area proportion of the metal member 120 per unit area in the first portion 101 is 0%, the area proportion of the metal member 120 per unit area in the second portion 102 is higher than 0% and lower than 100%, and the area proportion of the metal member 120 per unit area in the third portion 103 is 100%.

As a result, the light transmittance of the second portion 102 is lower than the light transmittance of the first portion 101, and the light transmittance of the third portion 103 is lower than the light transmittance of the second portion 102. For example, the light transmittance of the second portion 102 is in a range from 10% to 90% of the light transmittance of the first portion 101.

### Step of Disposing Resist Material Layer 20

Then, the method for manufacturing a laminate according to the present embodiment will be described.

First, an intermediate body 10 is provided. The intermediate body 10 is, for example, a substrate or a structure. In a case of a substrate, for example, the intermediate body 10 may be a semiconductor substrate such as a silicon substrate, a crystal growth substrate such as a sapphire substrate, or a wiring substrate. In a case of a structure, for example, the intermediate body 10 may be a semiconductor structure having a plurality of semiconductor layers, or a wiring structure.

Subsequently, as illustrated in FIG. 3, a resist material layer 20 made of a negative photoresist is disposed on the intermediate body 10. For example, the resist material layer 20 is disposed on the entire upper surface 15 of the intermediate body 10 by applying a negative photoresist. An upper surface 21 of the resist material layer 20 is preferably a flat surface or a nearly flat surface.

### Step of Exposing Resist Material Layer 20 to Light

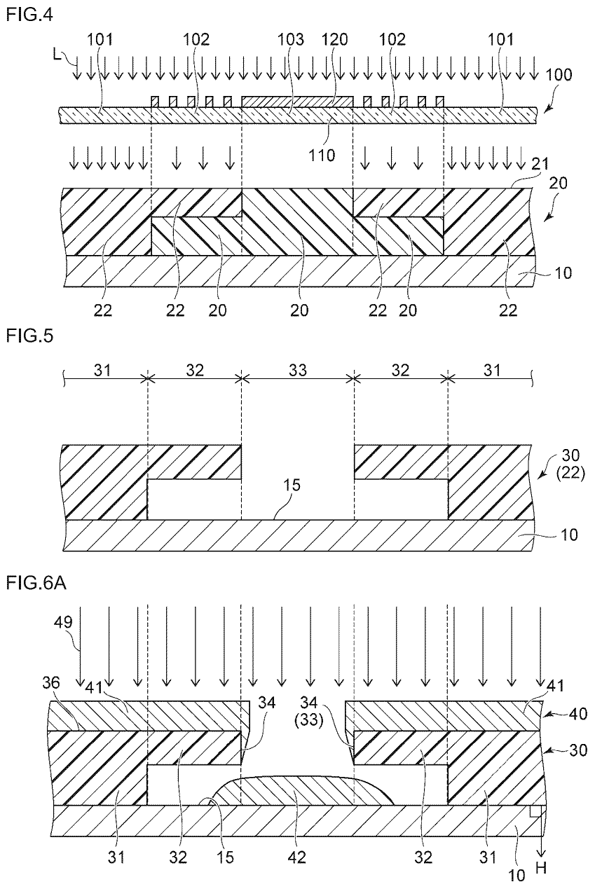

As illustrated in FIG. 4, the resist material layer 20 is exposed to light using the above-described mask 100. At this time, light L used for exposure is focused on the upper surface 21 of the resist material layer 20. In the first portion 101 of the mask 100, most of the light L is transmitted and irradiated to the resist material layer 20. In the second portion 102, a part of the light L is transmitted and irradiated to the resist material layer 20. That is, the amount of light transmitted through the second portion 102 is less than the amount of light transmitted through the first portion 101. In the third portion 103, most of the light L is blocked, and the resist material layer 20 is not substantially irradiated with the light L. The peak wavelength of light from a light source used in the exposure of the resist material layer 20 to light is, for example, in a range from 300 nm to 500 nm.

The solubility of the negative resist material layer 20 in a developer decreases in a portion irradiated with the light L. Hereinafter, the portion of the resist material layer 20 irradiated with the light L and having decreased solubility in the developer is referred to as an “exposed portion 22.” In a portion of the resist material layer 20 irradiated with light transmitted through the first portion 101 of the mask 100, the entire portion in a thickness direction becomes the exposed portion 22. In a portion of the resist material layer 20 irradiated with light transmitted through the second portion 102 of the mask 100, only an upper portion becomes the exposed portion 22, and a lower portion remains unexposed as the resist material layer 20. In a portion of the resist material layer 20 irradiated with light transmitted through the third portion 103 of the mask 100, the exposed portion 22 is not generated, and the entire portion remains unexposed as the resist material layer 20.

### Step of Forming Resist Layer

Subsequently, as illustrated in FIG. 5, the resist material layer 20, after the exposure to light, is developed using a developer. As the developer, for example, an organic solvent is used. Thus, of the resist material layer 20, the exposed portion 22 with decreased solubility remains, and a portion other than the exposed portion 22 is dissolved. As a result, a resist layer 30 composed of the exposed portion 22 is formed on the intermediate body 10. The resist layer 30 has a thickness, for example, in a range from 0.5 μm to 15 μm, preferably in a range from 1.0 μm to 10 μm, and more preferably in a range from 1.0 μm to 5.0 μm. In the present specification, the term “thickness” refers to the maximum thickness of each member in the thickness direction.

A first region 31, a second region 32, and an opening 33 are formed in the resist layer 30. The first region 31 is disposed in a region corresponding to the first portion 101 of the mask 100, and is in contact with the intermediate body 10. The second region 32 is disposed in a region corresponding to the second portion 102 of the mask 100, is spaced apart from the intermediate body 10, and is connected to the first region 31. The opening 33 is formed in a region corresponding to the third portion 103 of the mask 100. The opening 33 and a region located immediately below the second region 32 are connected to each other. In the opening 33 and the second region 32, the upper surface 15 of the intermediate body 10 is exposed from the resist layer 30. In a top view, the width of the second region 32 is, for example, in a range from 1.0 μm to 6.0 μm, more preferably in a range from 2.0 μm to 5.0 μm. The second region 32 has a thickness, for example, in a range from 40% to 90%, preferably in a range from 50% to 80%, of the thickness of the first region 31. The thickness of the second region 32 is, for example, in a range from 1.0 μm to 5.0 μm. The thickness of the second region 32 can be changed by, for example, appropriately adjusting the light transmittance of the second portion 102 of the mask 100.

### Step of Forming Covering Layer 40

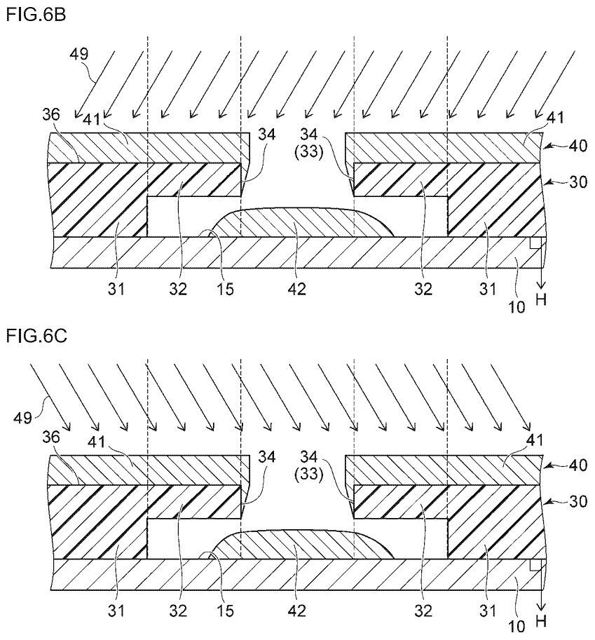

Subsequently, as illustrated in FIGS. 6A to 6C, a covering material is disposed on the intermediate body 10 and the resist layer 30. For example, a covering material is deposited on the intermediate body 10 and the resist layer 30 by sputtering. The covering material is, for example, a metal. However, the covering material may not be a metal but may be, for example, an insulating material.

At this time, as illustrated in FIG. 6A, a covering material 49 is supplied along a direction H perpendicular to the upper surface 15 of the intermediate body 10 to form a covering layer 40 on the upper surface 15 of the intermediate body 10 and an upper surface 36 of the resist layer 30. Alternatively, as illustrated in FIGS. 6B and 6C, the covering material 49 may be supplied along a direction inclined with respect to the direction H to form the covering layer 40 on the upper surface 15 of the intermediate body 10 and the upper surface 36 of the resist layer 30. For example, the covering layer 40 may be formed by supplying the covering material 49 along the direction H and the direction inclined with respect to the direction H.

In this way, the covering layer 40 is formed on the intermediate body 10 and the resist layer 30. The covering layer 40 is formed on the entire upper surface 36 of the resist layer 30 and on an inner lateral surface 34 of the opening 33. The covering layer 40 is also formed on the upper surface 15 of the intermediate body 10 in a region overlapping the opening 33 of the resist layer 30 and around the region overlapping the opening 33. The thickness of the covering layer 40 formed in the region overlapping the opening 33 is substantially uniform. As the distance from the region overlapping the opening 33 increases, the thickness of the covering layer 40 around the region overlapping the opening 33 decreases, compared with the thickness of the covering layer 40 formed in the region overlapping the opening 33.

On the other hand, the covering layer 40 exposes at least a part of a surface of the resist layer 30 other than the upper surface 36. For example, the covering layer 40 is not disposed on a lateral surface of the first region 31 of the resist layer 30 and a lower surface of the second region 32 of the resist layer 30. Therefore, a first portion 41 of the covering layer 40, the first portion 41 being in contact with the resist layer 30, is not connected to a second portion 42 of the covering layer 40, the second portion 42 being in contact with the intermediate body 10. That is, the first portion 41 disposed on the upper surface 36 of the resist layer 30 and on the inner lateral surface 34 of the opening 33 is not connected to the second portion 42 deposited in the region overlapping the opening 33 of the resist layer 30 and around the region overlapping the opening 33.

### Removing Step

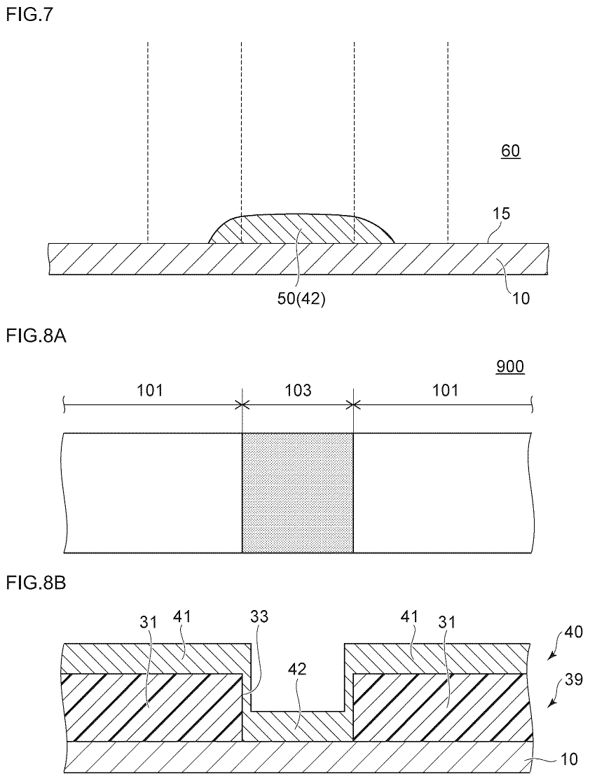

Subsequently, as illustrated in FIG. 7, the resist layer 30 is removed. Thus, of the covering layer 40, the first portion 41, which is in contact with the resist layer 30 is also removed together with the resist layer 30, and the second portion 42, which is not in contact with the resist layer 30, remains. A member 50 is formed by the second portion 42 of the covering layer 40. The member 50 is, for example, wiring made of a metal material. A laminate 60 is manufactured by forming the member 50 on the intermediate body 10. In a case in which the intermediate body 10 is a semiconductor structure including a plurality of semiconductor layers, the member 50 functions as, for example, an electrode electrically connected to the semiconductor structure. The resist layer 30 is removed using, for example, a solution that can remove the resist layer 30.

### Effect

According to the present embodiment, by exposing the negative resist material layer 20 to light using the mask 100 having the second portion 102, the second region 32 spaced apart from the intermediate body 10 can be formed in the resist layer 30 after developing the resist material layer 20. Thus, when the covering layer 40 is deposited, the first portion 41 of the covering layer 40 that is in contact with the resist layer 30, and the second portion 42 of the covering layer 40 that is in contact with the intermediate body 10 can be separated from each other. As a result, when the resist layer 30 is removed, only the first portion 41 of the covering layer 40 can be removed and the second portion 42 of the covering layer 40 can be left, and the generation of burrs on the member 50 can be reduced.

### Comparative Example

A comparative example will be described to describe the effect of the above-described first embodiment.

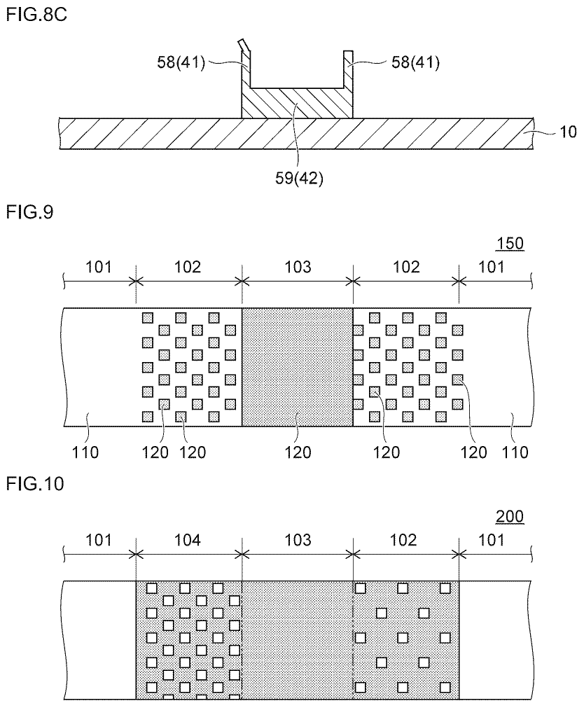

FIG. 8A illustrates a mask used in the present comparative example.

FIGS. 8B and 8C are each a cross-sectional view illustrating a method for manufacturing a laminate according to the present comparative example.

As illustrated in FIG. 8A, a mask 900 of the present comparative example includes a first portion 101 and a third portion 103, but does not include a second portion 102. The configurations of the first portion 101 and the third portion 103 are the same as those of the mask 100 in the first embodiment.

As illustrated in FIG. 8B, when the negative resist material layer 20 is exposed to light using the mask 900 and developed, the first region 31 and the opening 33 are formed but the second region 32 is not formed in the resist layer 39. When a covering material is deposited in this state, a first portion 41 of the covering layer 40, the first portion 41 being in contact with the resist layer 39, and a second portion 42 of the covering layer 40, the second portion 42 being in contact with the intermediate body 10, are connected to each other.

Thereafter, as illustrated in FIG. 8C, when the resist layer 39 is removed, most of the first portion 41 of the covering layer 40 is removed, but there is a possibility that a portion of the first portion 41 that is in contact with the second portion 42 cannot be completely removed. In this case, burrs 58 may be formed on a member 59.

### Modified example of First Embodiment

The present modified example is different from the first embodiment in the mask used for exposure.

FIG. 9 is a plan view illustrating a mask used in the present modified example.

As illustrated in FIG. 9, in a mask 150 of the present modified example, a plurality of metal members 120 are disposed to be spaced apart from each other in the second portion 102. Each of the metal members 120 in a top view has a shape that is, for example, square or circular. The metal members 120 in the second portion 102 are arranged in, for example, a rectangular lattice pattern or a triangular lattice pattern. In the example illustrated in FIG. 9, the metal members 120 in the second portion 102 are arranged in a square lattice pattern.

The configurations of the first portion 101 and the third portion 103 of the mask 150 of the present modified example are the same as those of the mask 100 of the first embodiment. Also with such a configuration, the same effect as that of the first embodiment can be obtained. The configuration, operation, and effects of the present modified example other than those described above are the same as those of the first embodiment.

### Second Embodiment

The present embodiment is different from the first embodiment in the shape of the intermediate body and the mask used for exposure. The configuration of the present embodiment other than the shape of the intermediate body and the mask is the same as that of the first embodiment.

FIG. 10 is a plan view illustrating a mask used in the present embodiment.

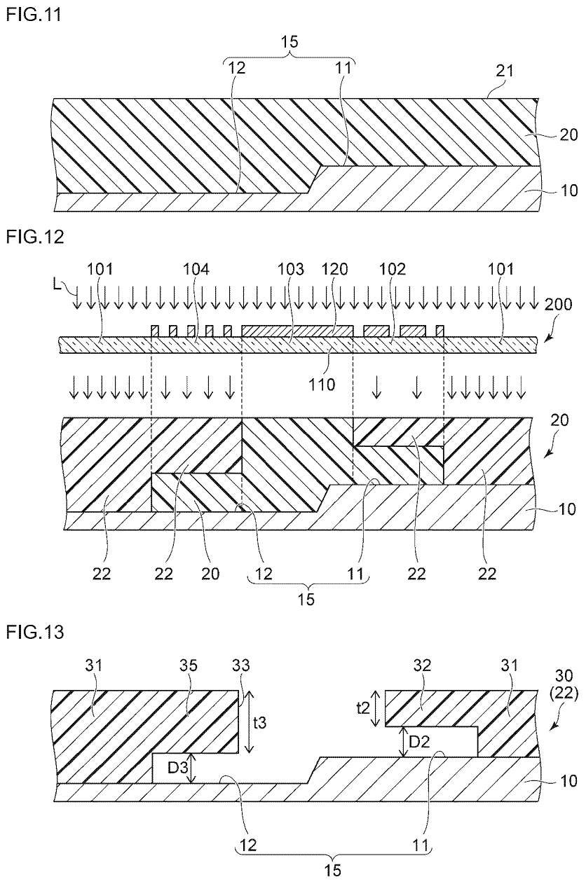

FIGS. 11 to 13 are each a cross-sectional view illustrating a method for manufacturing a laminate according to the present embodiment.

First, a mask for exposure used in the present embodiment will be described.

As illustrated in FIG. 10, a mask 200 used in the present embodiment includes a fourth portion 104 in addition to the first portion 101, the second portion 102, and the third portion 103. The light transmittance of the fourth portion 104 is lower than the light transmittance of the first portion 101 and higher than the light transmittance of the second portion 102. That is, the amount of light transmitted through the fourth portion 104 is less than the amount of light transmitted through the first portion 101 and more than the amount of light transmitted through the second portion 102.

In the example illustrated in FIG. 10, the second portion 102 and the fourth portion 104 are each disposed between the first portion 101 and the third portion 103 in a top view. The third portion 103 is disposed between the second portion 102 and the fourth portion in a top view. That is, in the mask 200, the first portion 101, the fourth portion 104, the third portion 103, the second portion 102, and the first portion 101 are arranged in this order in a region illustrated in FIG. 10.

Subsequently, the method for manufacturing a laminate according to the present embodiment will be described.

As illustrated in FIG. 11, in the present embodiment, the upper surface 15 of the intermediate body 10 includes a first surface 11 and a second surface 12 having different heights. The second surface 12 is disposed at a position lower than the first surface 11. The upper surface 15 of the intermediate body 10 has a step. A resist material layer 20 made of a negative photoresist is disposed on the intermediate body 10. An upper surface 21 of the resist material layer 20 is preferably a flat surface or a nearly flat surface.

Subsequently, as illustrated in FIG. 12, the resist material layer 20 is exposed to light using the mask 200. At this time, the second portion 102 of the mask 200 is disposed in a region corresponding to the first surface 11 of the upper surface 15 of the intermediate body 10, and the fourth portion 104 of the mask 200 is disposed in a region corresponding to the second surface 12 of the upper surface 15 of the intermediate body 10. The first portion 101 of the mask 200 is disposed in a region in which the entire resist material layer 20 is to become the exposed portion 22, and the third portion 103 of the mask 200 is disposed in a region in which the opening 33 is to be formed.

In a portion of the resist material layer 20 irradiated with light transmitted through the fourth portion 104 of the mask 200, only the upper portion becomes the exposed portion 22, and the lower portion remains unexposed as the resist material layer 20. Of the resist material layer 20, the exposed portion 22 formed in the portion corresponding to the fourth portion 104 of the mask 200 is thicker than the exposed portion 22 formed in the portion corresponding to the second portion 102. This is because, as described above, the amount of light transmitted through the fourth portion 104 is more than the amount of light transmitted through the second portion 102. As in the first embodiment, of the resist material layer 20, the entire portion corresponding to the first portion 101 of the mask 200 becomes the exposed portion 22, and the exposed portion 22 is not formed in the portion corresponding to the third portion 103.

Subsequently, as illustrated in FIG. 13, the resist material layer 20 is developed. Thus, the exposed portion 22 of the resist material layer 20 remains to form a resist layer 30. The resist layer 30 includes a third region 35 in addition to the first region 31, the second region 32, and the opening 33. The third region 35 is a region irradiated with the light L transmitted through the fourth portion 104 of the mask 200. That is, the third region 35 is disposed in a region corresponding to the fourth portion 104 of the mask 200. The third region 35 is spaced apart from the intermediate body 10. A thickness t3 of the third region 35 of the resist layer 30 is thicker than a thickness t2 of the second region 32. The second region 32 is disposed on the first surface 11 of the intermediate body 10, and the third region 35 is disposed on the second surface 12 of the intermediate body 10.

By setting the thickness t2 of the second region 32 and the thickness t3 of the third region 35 in consideration of the difference in height between the first surface 11 and the second surface 12, a distance D2 between the first surface 11 of the intermediate body 10 and the second region 32 of the resist layer 30 is made substantially equal to a distance D3 between the second surface 12 of the intermediate body 10 and the third region 35 of the resist layer 30. The distance D2 being substantially equal to the distance D3 means, for example, that the distance D2 is in a range from 90% to 110% of the distance D3. The distance D2 is the maximum length between the first surface 11 of the intermediate body 10 and the second region 32 of the resist layer 30 in the thickness direction. The distance D3 is the maximum length between the second surface 12 of the intermediate body 10 and the third region 35 of the resist layer 30 in the thickness direction.

According to the present embodiment, by using the mask 200 having the fourth portion 104, the intensity of light transmitted through the fourth portion 104 can be made higher than the intensity of light transmitted through the second portion 102, and the third region 35 can be formed in the resist layer 30. The thickness t3 of the third region 35 of the resist layer 30 is thicker than the thickness t2 of the second region 32. By disposing the second region 32 on the first surface 11 of the intermediate body 10 and disposing the third region 35 on the second surface 12 of the intermediate body 10, the distance D2 is made substantially equal to the distance D3. In this way, even in a case in which there is a step on the upper surface 15 of the intermediate body 10, the distance between the intermediate body 10 and the resist layer 30 can be made close to uniform. As a result, even in a case in which there is a step on the upper surface 15 of the intermediate body 10, it is possible to reduce the generation of burrs on the member 50. The manufacturing method and effects of the present embodiment other than those described above are the same as those of the first embodiment.

### Third Embodiment

The present embodiment is different from the first embodiment in the mask used for exposure. The configuration of the present embodiment other than the mask is the same as that of the first embodiment.

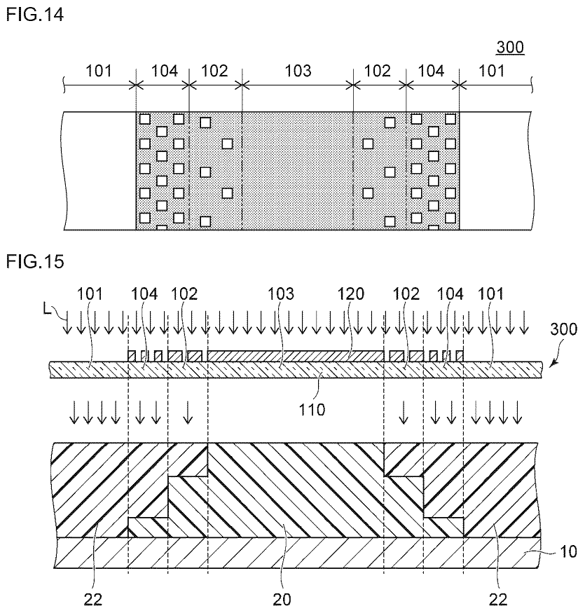

FIG. 14 is a plan view illustrating a mask used in the present embodiment.

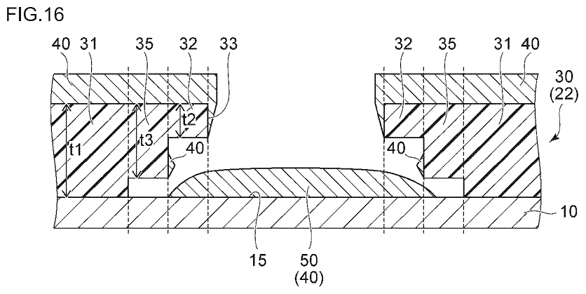

FIGS. 15 and 16 are each a cross-sectional view illustrating a method for manufacturing a laminate according to the present embodiment.

First, a mask for exposure that is used in the present embodiment will be described. As illustrated in FIG. 14, a mask 300 used in the present embodiment includes a fourth portion 104 in addition to the first portion 101, the second portion 102, and the third portion 103. The light transmittance of the fourth portion 104 is lower than the light transmittance of the first portion 101 and higher than the light transmittance of the second portion 102.

The fourth portion 104 is disposed between the first portion 101 and the second portion 102 in a top view. The second portion 102 is disposed between the third portion 103 and the fourth portion 104. That is, in the mask 300, the first portion 101, the fourth portion 104, the second portion 102, the third portion 103, the second portion 102, the fourth portion 104, and the first portion 101 are arranged in this order in the region illustrated in FIG. 14.

Then, the method for manufacturing a laminate according to the present embodiment will be described.

As illustrated in FIG. 15, in the present embodiment, the resist material layer 20 is exposed to light using the mask 300. As in the second embodiment, of the resist material layer 20, the exposed portion 22 formed in the portion corresponding to the fourth portion 104 of the mask 300 is thicker than the exposed portion 22 formed in the portion corresponding to the second portion 102. Further, the entire portion corresponding to the first portion 101 of the mask 300 becomes the exposed portion 22, and the exposed portion 22 is not formed in the portion corresponding to the third portion 103.

Subsequently, as illustrated in FIG. 16, the resist material layer 20 is developed. Thus, the exposed portion 22 of the resist material layer 20 remains to form a resist layer 30. The resist layer 30 includes a third region 35 in addition to the first region 31, the second region 32, and the opening 33. The third region 35 is a region irradiated with the light L transmitted through the fourth portion 104 of the mask 200, and is spaced apart from the intermediate body 10. A thickness t3 of the third region 35 of the resist layer 30 is thinner than a thickness t1 of the first region 31 and thicker than the thickness t2 of the second region 32.

Thus, a step is formed on the lower surface of the resist layer 30, and the distance between the intermediate body 10 and the resist layer 30 decreases as the distance from the region overlapping the opening 33 increases. As a result, on the upper surface 15 of the intermediate body 10, the covering material is less likely to reach a portion away from the region overlapping the opening 33 of the resist layer 30, and the covering layer 40 is less likely to be formed at such a portion. That is, because the supply of the covering material is obstructed by the third region 35, the covering layer 40 is formed on the lateral surface of the third region 35, and the covering layer 40 is less likely to be formed in the region immediately below the third region 35.

According to the present embodiment, the shape of the covering layer 40 can be controlled more accurately than in the first embodiment. As a result, the generation of burrs on the member 50 can be reduced more effectively. The manufacturing method and effects of the present embodiment other than those described above are the same as those of the first embodiment.

Each of the above-described embodiments and modified examples is an example embodying the present invention, and the present invention is not limited to these embodiments and modified examples. For example, in each of the above-described embodiments and modified examples, those in which some of the components or steps are added, omitted, or changed are also included in the present invention. The above-described embodiments and modified examples can be implemented in combination with each other.

What is claimed is:

1. A method for manufacturing a laminate, the method comprising:
disposing a resist material layer on an intermediate body, the resist material layer being made of a negative photoresist;
exposing the resist material layer to light using a mask comprising:
a first portion,
a second portion having a light transmittance lower than a light transmittance of the first portion, and
a third portion having a light transmittance lower than the light transmittance of the second portion, wherein:
the second portion is disposed between the first portion and the third portion in a top view;
developing the exposed resist material layer to form a resist layer comprising:
a first region disposed in a region corresponding to the first portion and in contact with the intermediate body,
a second region disposed in a region corresponding to the second portion, spaced apart from the intermediate body, and connected to the first region, and
an opening formed in a region corresponding to the third portion;
forming a covering layer on the resist layer and on the intermediate body such that at least a part of a surface of the resist layer other than an upper surface of the resist layer is exposed; and
removing the resist layer to remove a portion of the covering layer in contact with the resist layer.

2. The method for manufacturing a laminate according to claim 1, wherein, in the step of forming the covering layer, the covering layer is formed by sputtering.

3. The method for manufacturing a laminate according to claim 1, wherein the resist layer has a thickness in a range from 0.5 μm to 15 μm.

4. The method for manufacturing a laminate according to claim 1, wherein the light transmittance of the second portion is in a range from 10% to 90% of the light transmittance of the first portion.

5. The method for manufacturing a laminate according to claim 1, wherein:
the mask comprises a light-transmissive member, and a metal member disposed on the light-transmissive member;
an area of the metal member per unit area of the second portion is larger than an area of the metal member per unit area of the first portion; and
an area of the metal member per unit area of the third portion is larger than an area of the metal member per unit area of the second portion.

6. The method for manufacturing a laminate according to claim 5, wherein:
the metal member is not disposed in the first portion;
a plurality of openings are formed in the metal member in the second portion; and
the metal member is disposed in the entire third portion.

7. The method for manufacturing a laminate according to claim 5, wherein:
the metal member is not disposed in the first portion;
a plurality of the metal members are disposed to be spaced apart from each other in the second portion; and
the metal member is disposed in the entire third portion.

8. The method for manufacturing a laminate according to claim 1, wherein, in the step of exposing the resist material layer, the light used for exposure is focused on an upper surface of the resist material layer.

9. The method for manufacturing a laminate according to claim 1, wherein:
the mask further comprises a fourth portion disposed between the first portion and the second portion in a top view and having a light transmittance lower than the light transmittance of the first portion and higher than the light transmittance of the second portion; and
the resist layer comprises a third region disposed in a region corresponding to the fourth portion, spaced apart from the intermediate body, thicker than the second region, and disposed between the first region and the second region.

10. The method for manufacturing a laminate according to claim 1, wherein:
the mask further comprises a fourth portion having a light transmittance lower than the light transmittance of the first portion and higher than the light transmittance of the second portion;
an upper surface of the intermediate body comprises a first surface and a second surface disposed at a position lower than the first surface; and
the second portion of the mask is disposed in a region corresponding to the first surface of the upper surface of the intermediate body, and the fourth portion of the mask is disposed in a region corresponding to the second surface of the upper surface of the intermediate body.

11. The method for manufacturing a laminate according to claim 1, wherein:
the mask further comprises a fourth portion having a light transmittance lower than the light transmittance of the first portion and higher than the light transmittance of the second portion;
an upper surface of the intermediate body comprises a first surface and a second surface disposed at a position lower than the first surface;
in the step of exposing, the second portion of the mask is disposed in a region corresponding to the first surface of the upper surface of the intermediate body, and the fourth portion of the mask is disposed in a region corresponding to the second surface of the upper surface of the intermediate body; and
in the step of forming the resist layer, the resist layer comprises a third region disposed in a region corresponding to the fourth portion and spaced apart from the intermediate body, and a distance between the first surface of the intermediate body and the second region of the resist layer is equal to a distance between the second surface of the intermediate body and the third region of the resist layer.

12. The method for manufacturing a laminate according to claim 1, wherein, in the step of forming the covering layer, a portion of the covering layer in contact with the resist layer is not connected to a portion of the covering layer in contact with the intermediate body.
